(19) United States
(12) Patent Application Publication
(10) Pub. No.: US 2008/0174981 A1
(43) Pub. Date: Jul. 24, 2008

(54) PRE-MOLDED LEAD FRAME AND PROCESS FOR MANUFACTURING THE SAME

(76) Inventors: Say Teow CHAN, Singapore (SG); Yue Gen YU, Singapore (SG); Hong GU, Singapore (SG); Dawei XING, Singapore (SG); Yun ZHAO, Singapore (SG)

Correspondence Address: OSTROLENK FABER GERB & SOFFEN, 1180 AVENUE OF THE AMERICAS, NEW YORK, NY, 100368403, US

(21) Appl. No.: 11/774,182

(22) Filed: Jul. 6, 2007

Related U.S. Application Data
(60) Provisional application No. 60/886,410, filed on Jan. 24, 2007.

(51) Int. Cl. H05K 7/18; H01R 43/00

(52) U.S. Cl. 361/813; 29/827

(57) ABSTRACT

A lead frame and a method of manufacturing said lead frame is provided wherein a base material with first and second planar sides is first selectively etched from the first side thereof to a predetermined etching level to create etched areas. The etched areas on the first side of the said base material are then filled with a filling compound and thereafter, the base material is etched from the second side to the etching level to expose the filling compound on the second side.

### CROSS REFERENCE TO RELATED APPLICATIONS

This application claims the benefit and priority of U.S. Provisional Application Ser. No. 60/886,410 filed on Jan. 24, 2007, and entitled PRE-MOLDED LEAD FRAME AND PROCESS FOR MANUFACTURING THE SAME, the disclosure of which is incorporated herein by reference.

### FIELD OF THE INVENTION

The invention relates to electronic devices, and in particular to chip carriers such as lead frames that are used to support semiconductor integrated circuit chips during assembly and packaging of semiconductors.

### BACKGROUND AND PRIOR ART

Traditionally, lead frames are used to provide electrical interconnections to semiconductor circuit(s) mounted on them. Typically, the base material used for manufacturing the lead frames is copper alloy, stainless steel or alloy 42. However, the strong demand in higher performance devices with smaller and thinner package size but higher lead counts has resulted in a rapid increase in the use of laminate substrates such as Ball-Grid Array (“BGA”) packages, which are more expensive.

QFN (“Quad Flat No-Lead”) packages have been developed where molding compound is molded onto a lead frame on only one side of the lead frame. They are known for their small size, cost-effectiveness and good production yields. They are competitive in performance and efficiency with BGA packages. QFN packages also possess certain mechanical advantages for high-speed circuits including improved co-planarity and heat dissipation. Since QFN packages do not have gull wings leads which at times can act as antennas, creating “noise” in high-frequency applications, their electrical performance is superior to traditional leaded packages.

QFN packages are best used in low-lead count arrays. Nevertheless, another benefit of QFN packages, when compared to standard lead frame packages, is their ability to offer higher density interconnects. The leads of a QFN package are typically arranged in one, two or three-row configurations. QFN packages also take advantage of the fact that lead frame-based packaging is lower in cost than laminate-based substrates because it is less expensive to simply etch a thin piece of copper to form the lead frame than to fabricate a printed circuit board through many costly manufacturing steps.

However, existing lead frame manufacturing processes are still unable to produce lead frames which have a similar performance as compared to BGA packages, which can easily comprise multiple rows of electrical interconnects. It is clear that there exists a need to develop a new process of manufacturing a lead frame which can produce such high-performance lead frames.

### SUMMARY OF THE INVENTION

It is thus an object of the invention to develop a chip carrier such as a lead frame that can be used as an effective substitute for costlier BGA substrates. It is another object of the invention to produce a chip carrier having a relatively higher number of leads as compared to traditional lead frames, and which leads are adequately supported with an interlocking structure so that the lead frame is suitable for high-density packaging.

According to a first aspect of the invention, there is provided a method of manufacturing a lead frame, comprising the steps of: providing a base material with first and second planar sides; selectively etching the base material from the first side thereof to a predetermined etching level to create etched areas; filling the etched areas on the first side of the said base material with a filling compound; and thereafter etching the base material from the second side to the etching level to expose the filling compound on the second side.

According to a second aspect of the invention, there is provided a lead frame comprising: a base material having substantially planar first and second sides, the base material further defining at least one die pad and a plurality of leads separated by etched portions of the base material; and a filling compound formed at the etched portions of the base material for interlocking the die pad and the leads; wherein the filling compound is formed such that it is substantially flush with said first and second planar sides of the base material.

According to a third aspect of the invention, there is provided a lead frame comprising: a base material having substantially planar first and second sides, the base material further defining at least one die pad and a plurality of leads separated by etched areas of the base material; a filling compound formed at the etched areas of the base material for interlocking the die pad and the leads; and locking features in the form of indentations located along peripheral edges of the etched areas that are operative to lock the filling compound to the base material.

It would be convenient hereinafter to describe the invention in greater detail by reference to the accompanying drawings which illustrate preferred embodiments of the invention. The particularity of the drawings and the related description is not to be understood as superseding the generality of the broad identification of the invention as defined by the claims.

### BRIEF DESCRIPTION OF THE DRAWINGS

The features of a lead frame and its manufacture according to the present invention may be more fully understood from the following detailed description, read in conjunction with the accompanying drawings, wherein:

FIG. 1 is a partially cut-away plan view of a lead frame according to the preferred embodiment of the invention;

FIGS. 2a through 2f illustrate cross-sectional views of a base material at various stages during a first part of a manufacturing process wherein a filling compound is incorporated to the base material to produce the lead frame of FIG. 1;

FIGS. 3a through 3d illustrate cross-sectional views of the base material at various stages during a second part of a manufacturing process according to a first preferred embodiment of the invention to produce a finished lead frame;

FIGS. 4a through 4g illustrate cross-sectional views of the base material at various stages during a second part of a manufacturing process according to a second preferred embodiment of the invention to produce a finished lead frame;

FIGS. 5a through 5d illustrate various layouts of lead frames that may be produced utilizing the manufacturing processes according to the preferred embodiments of the invention; and

FIGS. 6a through 6e illustrate various features that serve to enhance locking to filling compound and prevent mold void formation during the molding of the lead frames according to the preferred embodiments of the invention.

### DETAILED DESCRIPTION OF THE PREFERRED EMBODIMENTS OF THE INVENTION

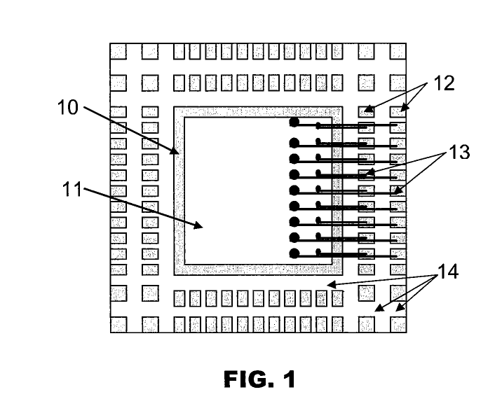

FIG. 1 is a partially cut-away plan view of a lead frame according to the preferred embodiment of the invention used to support a semiconductor die 11. The lead frame comprises leads 12 and a die pad 10 on which the semiconductor die 11 is bonded. The semiconductor die is connected to the leads 12 using fine wire 13, typically gold wire. The leads 12 and die pad 10 are plated with a first layer of nickel and nickel alloy, and a second layer of palladium, gold, silver and their alloys to enhance connectivity between the leads 12 and the wires 13, as well as to enhance solderability of the leads 12 and die pad 10 onto a print circuit board. Desirably, the lead frame comprises inner and outer rings of leads 12 to increase the density of electrical connections in the lead frame.

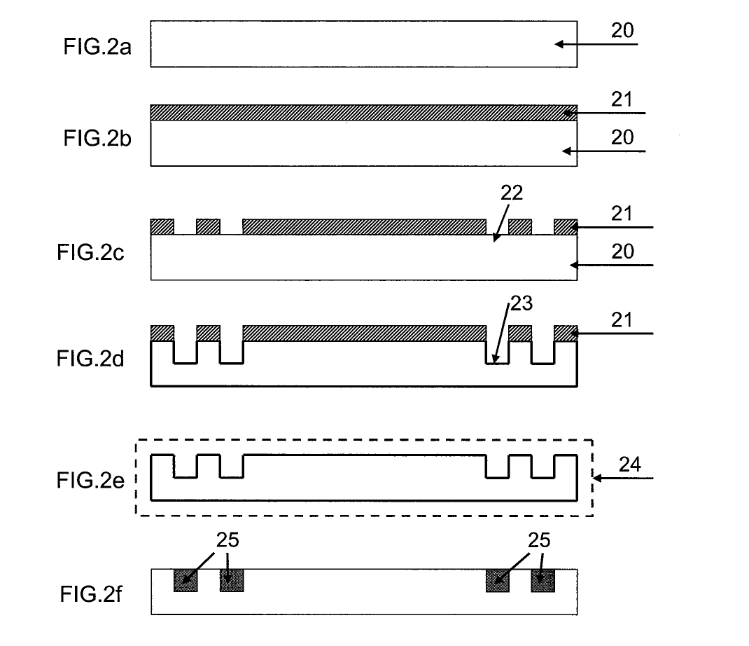

FIGS. 2a through 2f illustrate cross-sectional views of a base material at various stages during a first part of a manufacturing process wherein the base material is to produce the lead frame of FIG. 1. FIG. 2a illustrates a metallic base material comprised of a base metal 20 having first and second planar sides from which a lead frame is to be formed. The base material may, for instance, comprise a thin sheet of copper with a thickness of about 0.003 to 0.020 inch.

FIG. 2b illustrates that a layer of photoresist 21 has been applied to a surface on the first side of base metal 20. The photoresist 21 may comprise a light-sensitive acrylic polymer system, and may be applied in sheet form or as a liquid. Its thickness may range from from 0.0002 to 0.003 inch.

FIG. 2c illustrates the photoresist layer 21 having been masked, exposed to light and then developed to remove the unmasked areas of the photoresist layer 21 for exposing certain regions 22 of the base metal which are to be selectively etched away to form a lead frame pattern.

FIG. 2d illustrates the lead frame structure after a first half-etching process, during which the exposed regions 22 of the base metal 20 have been selectively etched away 23 at substantially half the thickness of the sheet of base metal 20 to a predetermined etching level to produce the desired lead frame pattern. This etching process is typically a wet etching process, which uses ferric chloride or cupric chloride as the etchant. In addition, there are many other well-known etching processes and etchants in the art, and it is not intended that the present invention be limited to any particular etching process.

In FIG. 2e, the remaining photoresist is stripped from the etched base material leaving a half-etched lead frame pattern 24. The stripping process is preferably accomplished using aqueous dissolution with an alkaline solution.

The etched areas on the first side of the base metal 20 are then filled with a filling compound 25. FIG. 2f illustrates the half-etched lead frame 24 after a filling compound 25 such as molding compound or plugging ink has been introduced into cavities in the half-etched areas of the lead frame 24 by molding or printing respectively. After this process, both the leads 12 and die pads 10 are surrounded and interlocked by hardened plastic molding compound or plugging ink. For compatibility with conventional downstream processes, the molding compound is preferably a thermoset type of plastic compound that is commonly used in the semiconductor packaging industry. After injecting the filling compound 25, deflashing of the molding compound or plugging ink bleed by either chemical deflash or mechanical deflash or both is preferably carried out to remove excess filling compound.

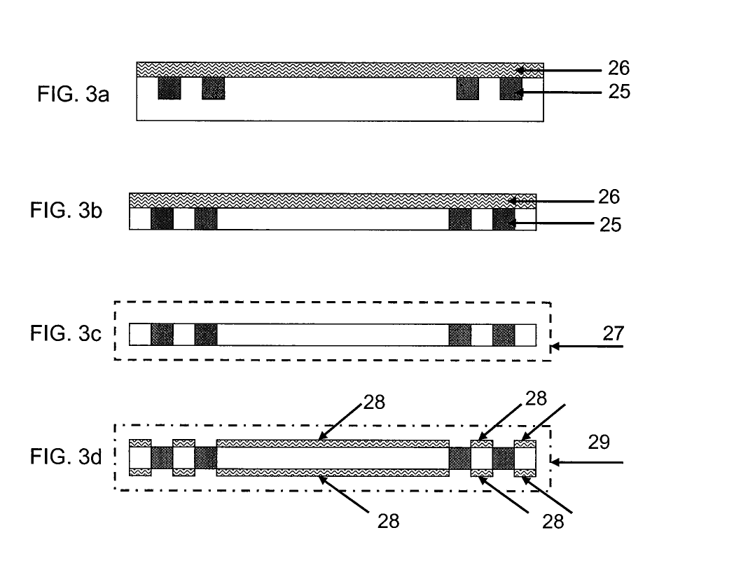

Thereafter, one of two options may be used to produce the final lead frame. FIGS. 3a through 3d illustrate cross-sectional views of the base material at various stages during a second part of a manufacturing process according to a first preferred embodiment of the invention to produce a finished lead frame. FIG. 3a illustrates the lead frame after lamination during which a tape, photoresist, print resist or other cover layer is applied to the first side as an etching mask 26 to cover the molded lead frame pattern for preventing the top surface of the first side (which has already been half-etched) from being etched further during a second etching process.

In FIG. 3b, substantially the whole of the uncovered surface on the second side has been half-etched without selective etching, and the lead frame structure 27 after the second etching process is illustrated. During this second etching process, the surface of the copper sheet that is not covered by etching mask has been etched away at substantially half the thickness of the base metal 20 to the etching level to produce the lead frame structure 27. This etching process is the same as the process described in FIG. 2d, but is preferably performed without selective masking so that the whole of the second side of the base metal 20 is etched to the etching level. After etching the base metal 20 from the second side, the filling compound 25 is exposed on the second side.

FIG. 3c illustrates the lead frame structure 27 after delamination or de-taping, during which the protection layer 26 used as an etching mask is removed. FIG. 3d illustrates the finished lead frame 29 after a plating process, during which several plating layers 28 are deposited onto the regions of the first and second sides of the base metal 20 not filled by filling compound 25. At first, an intermediate layer 28 of nickel or nickel alloy is applied, preferably by an electroless plating process. The thickness of the intermediate layer may typically be from 0.25 to 10 microns, and is more preferably in the range of 0.5 to 5 microns. Secondly, one or more protective layers may then be plated, preferably by an electroless plating or immersion process, in which at least one metal selected from the group consisting of palladium, palladium alloy, gold, gold alloy and silver is plated. The thickness of the protective layer is preferably in the range of 0.001 to 5 microns. Since the filling compound 25 is not a conductor of electricity, these plating layers 28 are not plated onto it. A lead frame according to the preferred embodiment of the invention is thereby produced.

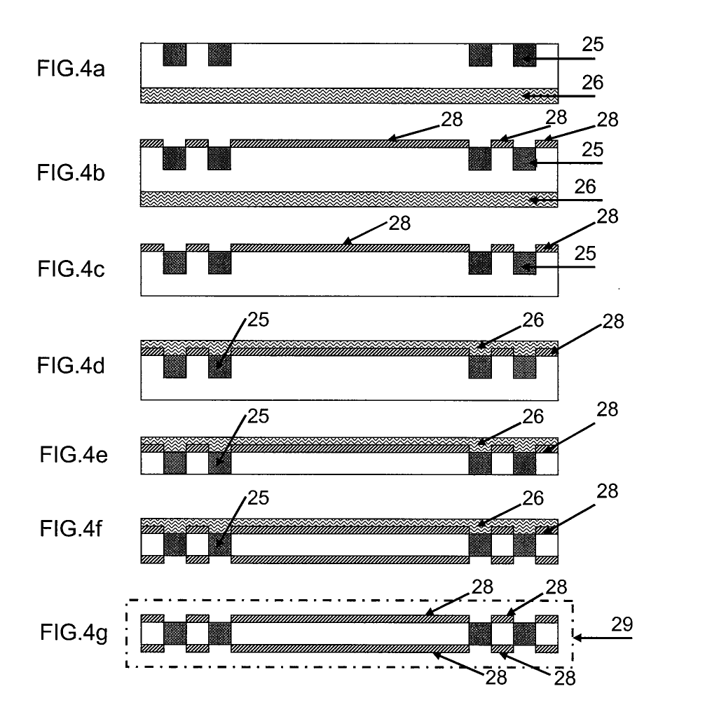

FIGS. 4a through 4g illustrate cross-sectional views of the base material at various stages during a second part of a manufacturing process according to a second preferred embodiment of the invention to produce a finished lead frame. In this embodiment, plating is first performed on one surface of the lead frame structure 27, more particularly on the first side. FIG. 4a illustrates the lead frame after lamination during which a tape, photoresist, print resist or other cover layer is applied as a plating mask 26 to cover the copper sheet for preventing plating occurring on the unfilled second side of the copper sheet during plating.

FIG. 4b illustrates the lead frame after plating, in which either a plating layer 28, which may comprise nickel/palladium, nickel/gold, nickel/palladium/gold and/or silver and tin may be plated, preferably by electroplating and/or electroless plating. The plating thickness of these plating layers 28 is preferably in the range of 0.001 to 5 microns.

FIG. 4c illustrates the lead frame structure after de-masking, in which the etching mask 26 used as a cover layer for the second side is removed.

FIG. 4d illustrates the lead frame structure after lamination during which a tape, photoresist, print resist or other cover layer such as an etching mask 26 is applied for preventing etching of the half-etched surface on the first side of the lead frame during a second etching process.

FIG. 4e illustrates the lead frame structure after second etching, during which the second side of the base material has been etched away at half the depth of the sheet to reveal the filling compound 25. This etching process is the same as the etching process described with respect to FIG. 3b.

FIG. 4f illustrates the lead frame after plating of the second side after etching the second side of the base metal 20. Several plating layers 28 have been deposited onto the regions that are not filled by filling compound 25. One option is to apply an intermediate layer of nickel or nickel alloy by plating, preferably by using electroless plating. The thickness of the nickel layer may typically be from 0.25 to 10 microns, and is more preferably in the range of 0.5 to 5 microns. Thereafter, one or more protective layers are then plated, preferably by electroless or immersion plating, during which at least one metal selected from the group consisting of palladium, palladium alloy, gold and gold alloy is plated. The thickness of the protective layer is preferably in the range of 0.001 to 5 microns. Another option is to plate a layer of silver or tin in the range of 0.001 to 5 microns, preferably by using electroless or immersion plating. Since filling compound 25 is not a conductor of electricity, these plating layers 28 do not plate onto it.

FIG. 4g illustrates the finished lead frame structure 29 after delamination or de-taping, during which the lamination used as an etching mask 26 or cover layer is removed.

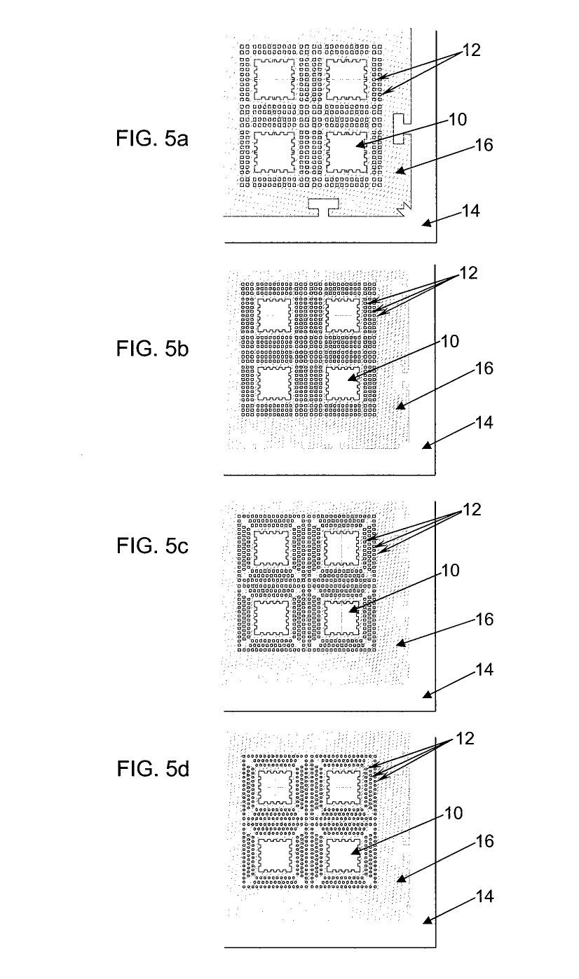

FIGS. 5a through 5d illustrate various layouts of lead frames that may be produced utilizing the manufacturing processes according to the preferred embodiments of the invention. FIG. 5a is a plan view of a lead frame 14 having a 2-row leads layout. In this configuration, there are two rows of leads 12 surrounding each die pad 10. Each die pad 10 is surrounded by a plurality of leads 12, and the leads 12 and die pad 10 are separated by etched areas 16 of the base material of the lead frame 14. Filling compound 25 is introduced into the etched areas 16 of the lead frame 14 for interlocking the die pad 10 and the leads 12. As shown in FIGS. 3d and 4g, the filling compound 25 is formed such that it is substantially flush with the first and second planar sides of the base material. The leads 12 may be square or rectangular in shape, and may be arranged in regular, in-line patterns.

FIG. 5b is a plan view of a lead frame 14 having a 3-row leads layout. In this configuration, there are three rows of leads 12 surrounding each die pad 10. The leads 12 may be square or rectangular in shape, and may be arranged in regular, in-line patterns. This layout enables the lead frame 14 to accommodate a higher lead count than the 2-row leads layout.

FIG. 5c is a plan view of another lead frame 14 having a 3-row leads layout, but the leads have a staggered pattern instead of a regular in-line pattern. This staggered pattern has the advantage that it facilitates a greater number of wire bonding loop layout options.

FIG. 5d is a plan view of yet another lead frame 14 having a 3-row staggered leads layout, but the leads 12 are etched in round shapes instead of quadrilateral shapes. The round leads 12 may help to facilitate the flow of molding compound during molding.

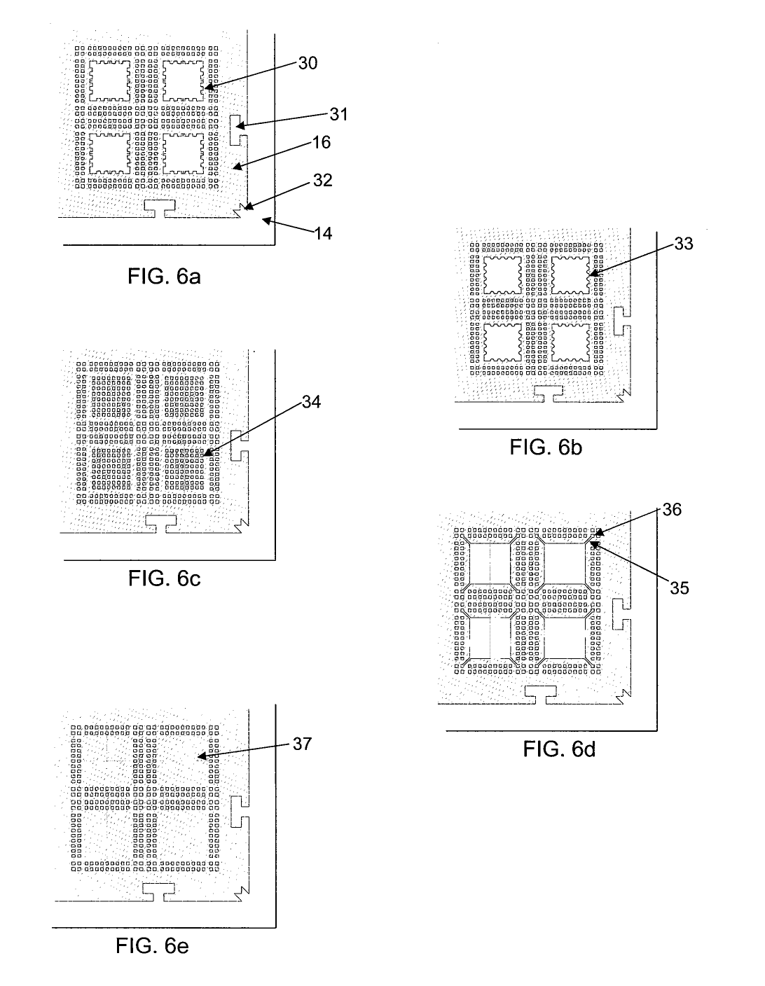

FIGS. 6a through 6e illustrate various features that serve to enhance mold locking and prevent mold void formation during the molding of the lead frames according to the preferred embodiments of the invention. FIG. 6a shows several features for enhancing locking to the filling compound and preventing mold void when molding the lead frame 14 with molding compound.

One locking feature comprises notch-in features 30 that may be in the form of multiple notches which are pre-etched and spaced along the edges of the die pad 10 which serve to lock the molded compound after molding, to prevent the molded compound from dislodging. The notch-in features 30 can also facilitate mold-flow and eliminate the mold void. These notch-in features may be quadrilateral, such as square or rectangular shaped.

Further locking features may be in the form of indentations along the peripheral edges of the etched areas 16 of the lead frame 14 that are operative to lock the filling compound 25 to the lead frame 14. The indentations may be substantially T-shaped along the sides of the etched areas 16, such as a T-lock 31, or may be substantially M-shaped at the corners, such as an M-lock 32. The T-lock 31 and M-lock 32 also help to prevent mold voids from being formed on molding panel edges of the lead frame 14.

FIG. 6b is a plan view of a lead frame 14 showing the mold locking and anti-voiding features in the form of notch-in features 33 on the edges of the die pad 10 that are semi-circular in shape. The semi-circular shapes show excellent performance in preventing mold voids.

FIG. 6c illustrates another mold locking feature on a die pad 10 where the whole die pad 10 is comprised by multiple small pads 34. Each small pad 34 may serve as a locking feature for the filling compound 25 when it is surrounded by filling compound 25 at the etched areas 16.

FIG. 6d illustrates exposed tie bars 35 that act as locking features to lock the filling compound to the base material. Each exposed tie bar 35 connects the die pad 10 to a corner lead 12, and the tie bars 35 are preferably located at the corners of each die pad 10. It is extremely useful when the die pad 10 is designed for a big die size. Moreover, the features of FIG. 6a and FIG. 6d can be combined to achieve better lead frame performance.

FIG. 6e is a plan view of a lead frame 14 that has no metallic die pad 10 on the lead frame 14. Instead of the metallic die pad 10, dice that are mounted on the lead frame 14 will sit directly on filling compound that has been introduced onto etched areas 16 of the lead frame 14 as described above at the die pad position.

In accordance with the present invention, there has thus been disclosed herein a method for manufacturing a lead frame by first etching a base material from one side of the base material and applying a filling compound such as molding compound or plugging ink as an interlocking lead frame pattern for holding the die pads and leads. Base material is then etched from an opposite side to expose the filling compound. This largely increases the lead count of the lead frame and also reduces the final package thickness.

A novel lead frame is also disclosed that uses a filling compound such as molding compound or plugging ink to interlock a lead frame pattern whereby to significantly increase the lead count and reduce the packaging thickness as compared to prior art approaches. The preferred embodiments of the present invention enable the production of a thinner lead frame with a thickness of as low as 2 mil. The process of the present invention also enables good adhesion between the lead frame and the filling compound interlocking it.

It should be recognized that the specifics of the various processes recited above, such as the types of photoresist, molding compound, plugging ink, print resist and tape used, the process of etching base material to form the lead frame, the process of molding or plugging ink to form a interlocking between leads and pads, the process of deflash for removing mold bleed and the process of depositing plating layers, are provided for illustrative purposes only, and that other processes and materials which provide equivalent results may be substituted therefor.

While the principles of the present invention have been demonstrated with particular regard to the method disclosed herein, it will be recognized that various departures may be undertaken in the practices of the invention. The scope of the invention is not intended to be limited to the particular method disclosed herein, but should instead be gauged by the breadth of the claims which follow.

1. Method of manufacturing a lead frame, comprising the steps of:
providing a base material with first and second planar sides;
selectively etching the base material from the first side thereof to a predetermined etching level to create etched areas;
filling the etched areas on the first side of the said base material with a filling compound; and thereafter
etching the base material from the second side to the etching level to expose the filling compound on the second side.

2. Method as claimed in claim 1, wherein the etching level is substantially at half the thickness of the base material.

3. Method as claimed in claim 1, wherein the filling compound comprises plugging ink.

4. Method as claimed in claim 3, wherein the step of filling the etched areas with filling compound comprises the step of printing said plugging ink onto the etched areas.

5. Method as claimed in claim 1, wherein the filling compound comprises molding compound.

6. Method as claimed in claim 1, further comprising the step of removing excess filling compound from the first side of the base material after introducing the filling compound.

7. Method as claimed in claim 1, further comprising the step of covering the first side of the base material while etching the base material from the second side when the second side is uncovered.

8. Method as claimed in claim 7, further comprising the step of depositing plating layers onto regions of the first and second sides of the base material that are not filled by filling compound after etching the second side.

9. Method as claimed in claim 1, wherein substantially the whole of the second side of the base material is etched to the etching level to expose the filling compound on the second side without selective etching.

10. Method as claimed in claim 1, further comprising the step of covering the second side of the base material and depositing plating layers onto the first side of the base material prior to etching the second side.

11. Method as claimed in claim 10, including the step of covering the first side of the base material that has been plated prior to etching the second side of the base material.

12. Method as claimed in claim 11, further comprising the step of depositing one or more plating layers on the second side after etching the second side of the base material.

13. A lead frame comprising:
a base material having substantially planar first and second sides, the base material further defining at least one die pad and a plurality of leads separated by etched areas of the base material; and
a filling compound formed at the etched areas of the base material for interlocking the die pad and the leads;
wherein the filling compound is formed such that it is substantially flush with said first and second planar sides of the base material.

14. The lead frame as claimed in claim 13, including locking features on the base material comprising multiple notches spaced along the edges of the die pad that are operative to lock the filling compound to the base material.

15. The lead frame as claimed in claim 14, wherein the notches comprise semi-circular or quadrilateral shapes.

16. The lead frame as claimed in claim 13, including a locking feature on the base material comprising a tie bar connecting a die pad to a lead that is operative to lock the filling compound to the base material.

17. The lead frame as claimed in claim 13, wherein each die pad comprises multiple small pads surrounded by filling compound that are operative to lock the filling compound to the die pad.

18. The lead frame as claimed in claim 13, including locking features on the base material comprising multiple indentations located along peripheral edges of the edged areas that are operative to lock the filling compound to the base material.

19. The lead frame as claimed in claim 18, wherein the multiple indentations are substantially T-shaped or M-shaped.

20. A lead frame comprising:
a base material having substantially planar first and second sides, the base material further defining at least one die pad and a plurality of leads separated by etched areas of the base material;
a filling compound formed at the etched areas of the base material for interlocking the die pad and the leads; and
locking features in the form of indentations located along peripheral edges of the etched areas that are operative to lock the filling compound to the base material.
